(19) United States
(12) Patent Application Publication
(10) Pub. No.: US 2008/0171427 A1
(43) Pub. Date: Jul. 17, 2008

(54) EEPROM MEMORY CELL WITH CONTROLLED GEOMETRICAL FEATURES

(75) Inventor: Bohumil Lojek, Colorado Springs, CO (US)

Correspondence Address: SCHNECK & SCHNECK, P.O. BOX 2-E, SAN JOSE, CA, 95109-0005, US

(73) Assignee: ATMEL CORPORATION, San Jose, CA (US)

(21) Appl. No.: 11/623,654

(22) Filed: Jan. 16, 2007

(51) Int. Cl. H01L 21/71; G03F 7/22

(52) U.S. Cl. 438/585; 257/E21.536

(57) ABSTRACT

A method of fabricating structures in an electronic device by forming and patterning a first film layer on a substrate into ridges with a photolithographic system. The ridges are formed from an image produced by a first simple geometry photomask where the first photomask has at least one first slot-like feature. The ridges are patterned into the structures which are essentially rectangular in shape and formed from an image produced by a second simple geometry photomask. The second photomask has at least one second slot-like feature arranged substantially orthogonal to the at least one first slot-like feature on the first photomask. The structures each have at least one dimension less than a limit-of-resolution of the photolithographic system where the dimension is measured in a plane substantially parallel to a face of the substrate.

### TECHNICAL FIELD

The present invention relates generally to methods for fabricating electronic devices, and more particularly to fabricating features in an electronic device below an optical limit of resolution.

### BACKGROUND ART

There is a need in the integrated circuit art for obtaining increasingly smaller devices without sacrificing device performance. The small device size requires small device regions, precise and accurate alignment between regions and minimization of parasitic resistances and capacitances. Device size can be reduced by putting more reliance on fine line lithography, but as discussed below, it becomes impractical or impossible to continue to reduce feature size and achieve the required greater increase in alignment accuracy. As lithography is pushed to the limit, yield and production throughput decrease.

Four governing performance parameters of a photolithographic system are limit-of-resolution, Lᵣ, level-to-level alignment accuracy, depth-of-focus, and throughput. For purposes of this discussion, limit-of-resolution is a physically-constrained parameter that affects a minimum feature size that can be fabricated.

Typical photolithographic techniques are limited by physical constraints of the photolithographic system involving actinic radiation wavelength, λ, and geometrical configurations of the projection system optics. According to Rayleigh's criterion,

$${L}_{r} = \frac{0.61 λ}{NA}$$

where NA is the numerical aperture of the optical system and is defined as NA=nsinα, where n is the index of refraction of the medium which the radiation traverses (usually air for this application, so n≅1) and α is a half-angle of the divergence of the actinic radiation (See EUGENE HECHT, OPTICS, 418-419 (2d ed. 1987) and Shinya Inoue & Rudolf Oldenbourg, Microscopes, in II HANDBOOK OF OPTICS: DEVICES, MEASUREMENTS, & PROPERTIES §0 17, at 17.7 (Michael Bass et., 1995)). Deep ultraviolet (DUV) radiation is generally considered to be in a range of 193 nm to 300 nm. Using, for example, DUV with λ=193 nm, and NA=0.7, the lower limit-of-resolution is 168 nanometers (1680 Å).

Techniques such as optical proximity correction (OPC) and phase-shifted masks (PSM) can extend the limit-of-resolution downward, but photomasks required in these techniques are extremely expensive. For example, OPC is generally viewed as a technique for improving critical dimension control and masks may include features such as serifs, hammerheads, and bias and assist bars. Each of these features adds greatly to the overall complexity and expense of a photomask. PSM masks may be used to circumvent the physical limit-of-resolution by enhancing contrast of the optical lithography process through use of complicated and expensive diffractive properties of a specially designed mask. PSM employs a mask that uses regions of shifted phase to improve stepper imaging performance. Through the use of PSM masks, resolution may be improved to some extent. However, PSM is generally viewed as a technique for improving depth of focus more than a means to improve resolution. Overall increased expenses with OPC and PSM masks becomes greatly compounded with a realization that an advanced semiconductor process may employ more than 25 photomasks.

A standard mask has an opaque light shielding layer (typically chromium oxide, Cr₂O₃) formed on a transparent quartz or glass substrate. The substrate allows transmission of light at a certain phase angle (0°). However, due to destructive interference of light occurring at edges of the light-shielding layer, the standard mask exhibits an actual reduction of a light-shielding area, causing difficulty in an accurate definition of a desired pattern. In contrast, the phase-shifted mask combines phases of light transmitting through the mask depending upon an arrangement of patterns in the mask along with various materials (e.g., Cr₂O₃ combined with other materials such as dielectric films) allow for phase-shifting of the incident actinic radiation.

With reference to FIG. 1, a plan view of an opening 101 in a standard mask 101 produces a resultant feature 103 on the wafer after processing. For example, the opening 101 in the standard mask is the shape of the desired target feature—a rectangular structure. However, the resultant feature 103 has severely rounded edges due to a combination of destructive interference of the transmitted radiation through the opening 101 along with wet chemical processing of the feature 103 (e.g., post polysilicon etch). The OPC opening 111 has serifs which reduce the rounding effect in a resultant etched feature 113. Nevertheless, the rounding still occurs. Finally, the PSM opening 121 uses various overlying materials (indicated by the solid and dashed lines) but nonetheless still produces a resultant etched feature 123 with rounded edges. Consequently, even though expensive mask technologies exist, they do not necessarily fully solve the problems with feature rounding especially when combined with etch effects.

Along with the limit-of-resolution, the second parameter, level-to-level alignment accuracy becomes more critical as feature sizes on photomasks decrease and a number of total photomasks increases. For example, if photomask alignment by itself causes a reduction in device yield to 95% per layer, then 25 layers of photomask translates to a total device yield of 0.95²⁵=0.28 or 28% yield (assuming independent errors). Therefore, a more complicated mask, such a phase-shifted mask, is not only more expensive but device yield can suffer dramatically.

For at least the aforementioned reasons, integrated circuit manufacturers have been unable to sufficiently reduce a size of electronic devices while still maintaining high performance at a reasonable cost. In view of the desire for integrated circuits having higher device counts, smaller device sizes, and greater circuit performance, a need continues to exist for an improved process to manufacture the required devices without resorting to unrealistic and expansive photolithography requirements.

Accordingly, what is needed is a way to provide an improved method for fabricating minimum feature sizes on integrated circuit devices while maintaining low costs and high yields.

### SUMMARY

In one exemplary embodiment, the present invention is a method of fabricating one or more floating gate elements in an EEPROM memory cell. The method includes forming a gate oxide layer on a substrate, forming a polysilicon layer over the gate oxide, and patterning the polysilicon layer into one or more ridges with a photolithographic system. The one or more ridges are formed from an image produced by a first simple geometry photomask. The first simple geometry photomask has at least one first feature. The one or more ridges are patterned into the one or more floating gate elements. The one or more floating gate elements are essentially rectangular in shape and formed from an image produced by a second simple geometry photomask. The second photomask has at least one second feature arranged substantially orthogonal to the at least one first feature on the first photomask.

In another exemplary embodiment, the present invention is a method of fabricating one or more floating gate elements in an EEPROM memory cell. The method includes forming a polysilicon layer on a substrate, forming a first photoresist layer over the polysilicon layer, selecting a first simple geometry photomask having at least one first slot-like feature, projecting an image onto the first photoresist layer from the first simple geometry photomask using a photolithographic system, and etching the polysilicon layer, thereby forming at least one ridge. A second photoresist layer is formed over the polysilicon layer and a second simple geometry photomask is selected having at least one second slot-like feature. The at least one second slot-like feature is arranged substantially orthogonal to the at least one first slot-like feature on the first simple geometry photomask. An image is projected onto the second photoresist layer from the second simple geometry photomask using the photolithographic system and the polysilicon layer is etched, thereby forming the floating gate.

In another exemplary embodiment, the present invention is a method of fabricating one or more structures in an electronic device. The method includes forming a first film layer on a substrate and patterning the first film layer into one or more ridges with a photolithographic system. The one or more ridges are formed from an image produced by a first simple geometry photomask where the first simple geometry photomask has at least one first slot-like feature. The one or more ridges are patterned into the one or more structures. The one or more structures are essentially rectangular in shape and formed from an image produced by a second simple geometry photomask. The second simple geometry photomask has at least one second slot-like feature arranged substantially orthogonal to the at least one first slot-like feature on the first photomask. The one or more structures each have at least one dimension less than a limit-of-resolution of the photolithographic system where the at least one dimension is measured in a plane substantially parallel to a face of the substrate.

### BRIEF DESCRIPTION OF THE DRAWINGS

FIG. 1 shows plan views of mask openings in various mask types employed in the prior art and resulting features produced by the masks.

FIGS. 2A and 2B provide a conceptual representation of masking techniques employed in various embodiments of the present invention.

FIGS. 3A-3H show plan and cross-sectional views of portions of an EEPROM memory cell at various fabrication stages in accord with an exemplary embodiment of the present invention.

### DETAILED DESCRIPTION

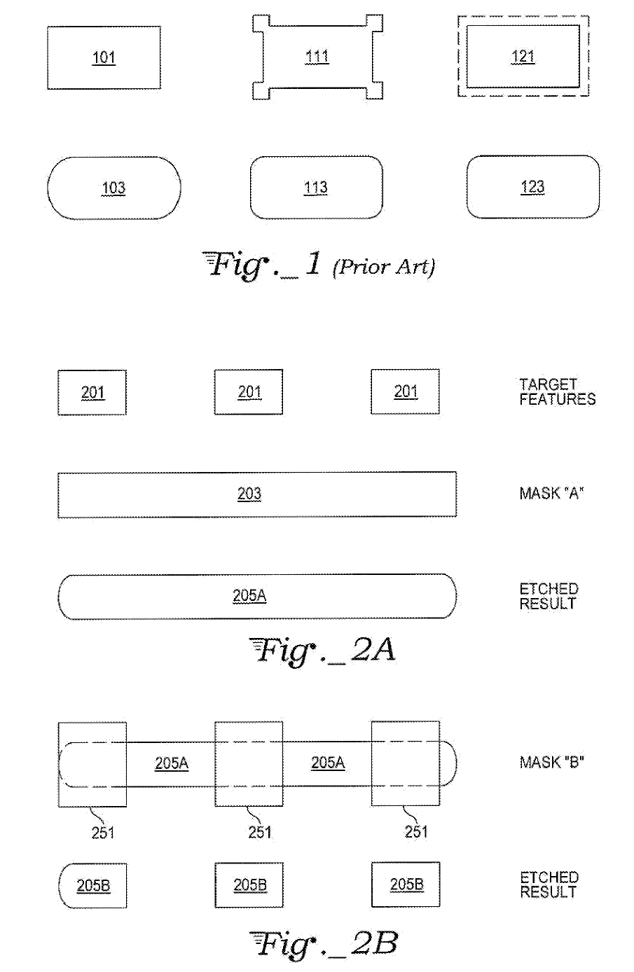

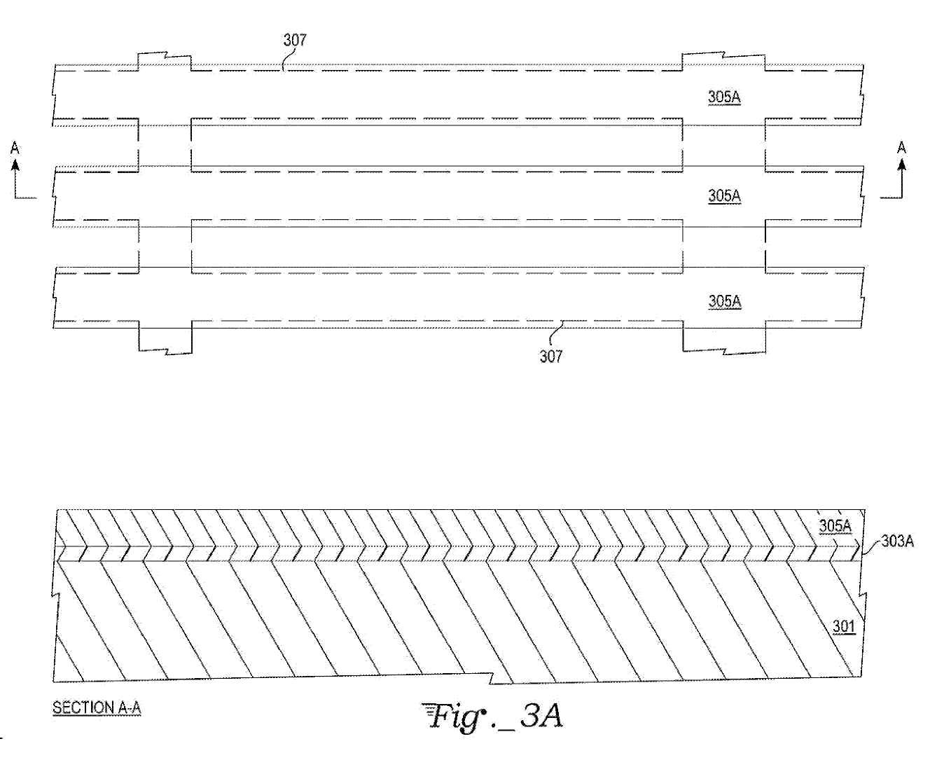

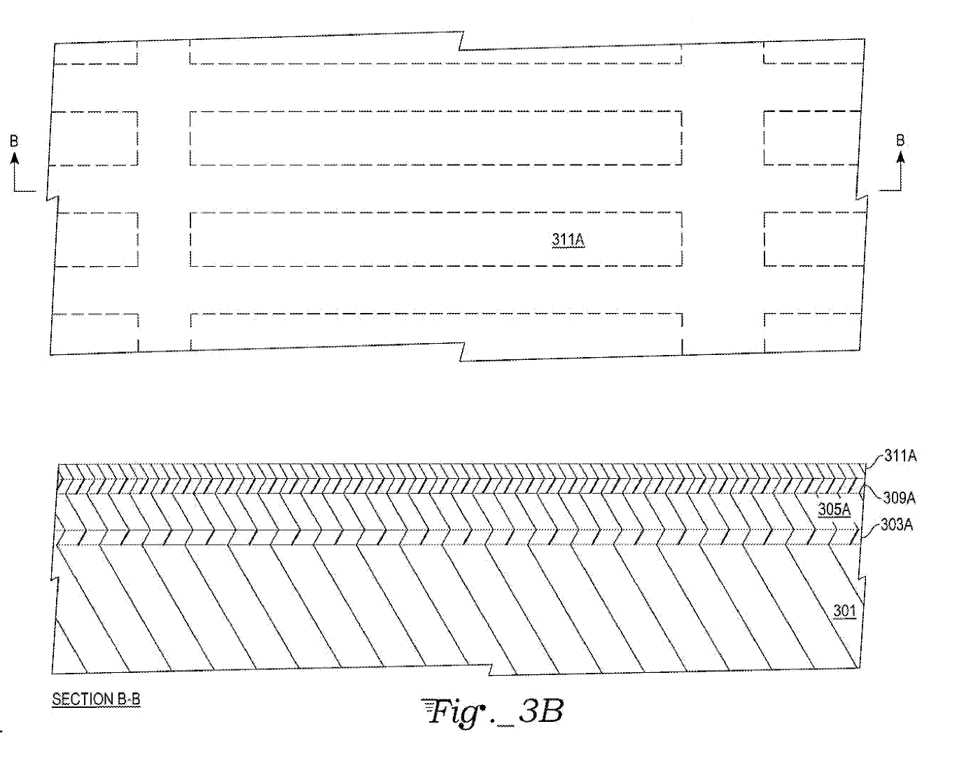

FIGS. 2A and 2B provide a conceptual overview of techniques presented in various embodiments of the present invention presented herein. With reference to FIG. 2A, a plan view indicates a shape of desired target features 201 produced during fabrication process. An opening 203 in a first mask (mask “A,” not shown) is used to produce a feature on a substrate (e.g., such as a silicon wafer, not shown). A resultant feature 205A produced after etching exhibits some corner rounding. In FIG. 2B, a second mask (mask “B,” not show) contains a plurality of openings 251. The plurality of openings 251 is shown relative to the resultant feature 205A produced by mask “A.” Resultant features 205B indicate a close match to the desired target features 201. A skilled artisan will recognize that any number of features may be produced by this two-mask technique. A skilled artisan will further recognize that all resulting features 205B may be produced with square corners depending upon a relative placement of mask “B” to the resultant feature 205A. The openings in both mask “A” and mask “B” are produced by standard photomask fabrication techniques. Neither OPC nor PSM is required.

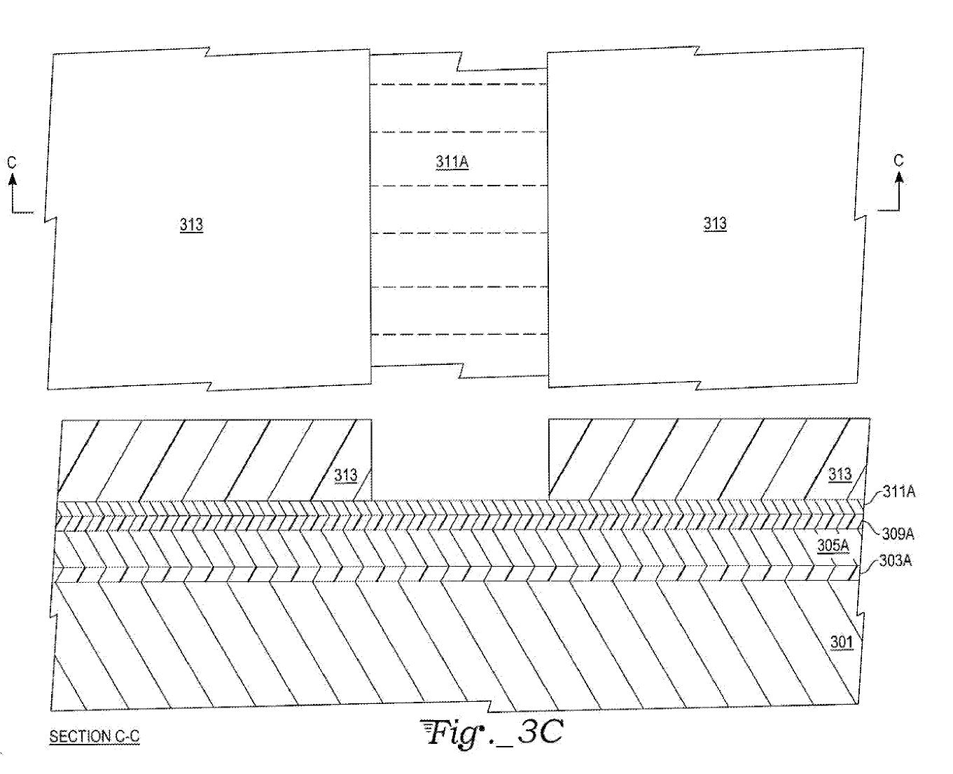

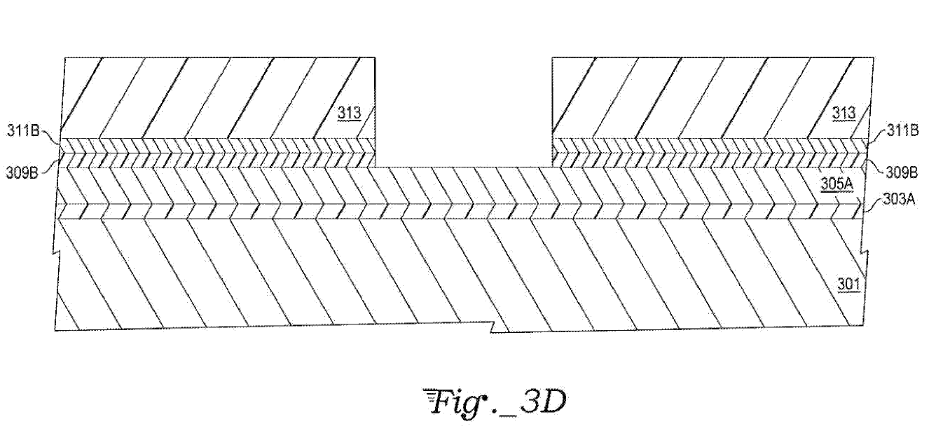

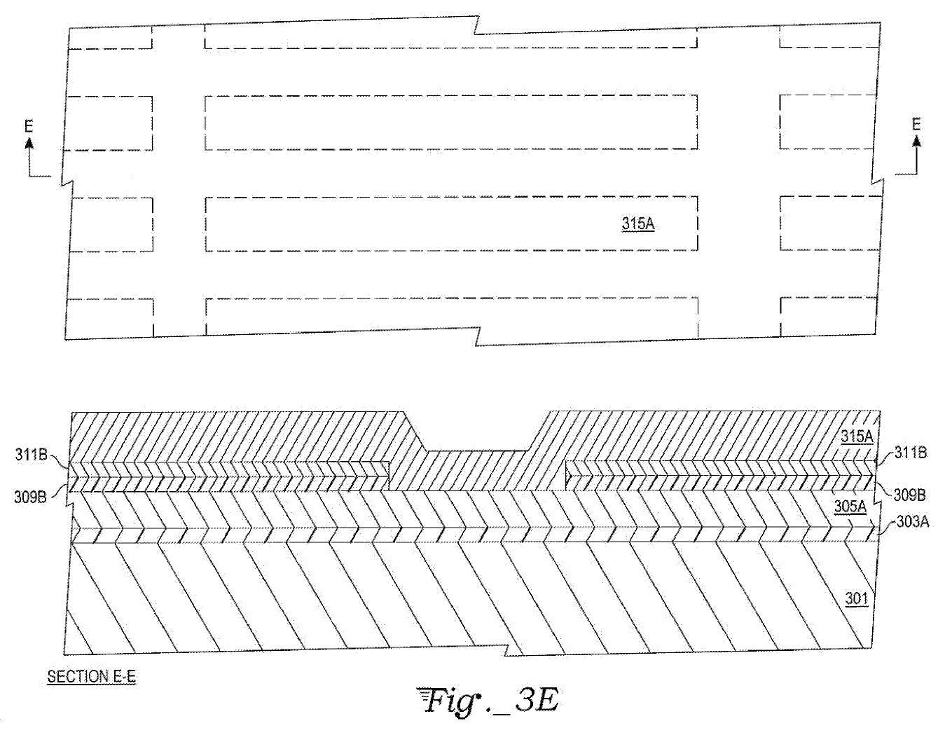

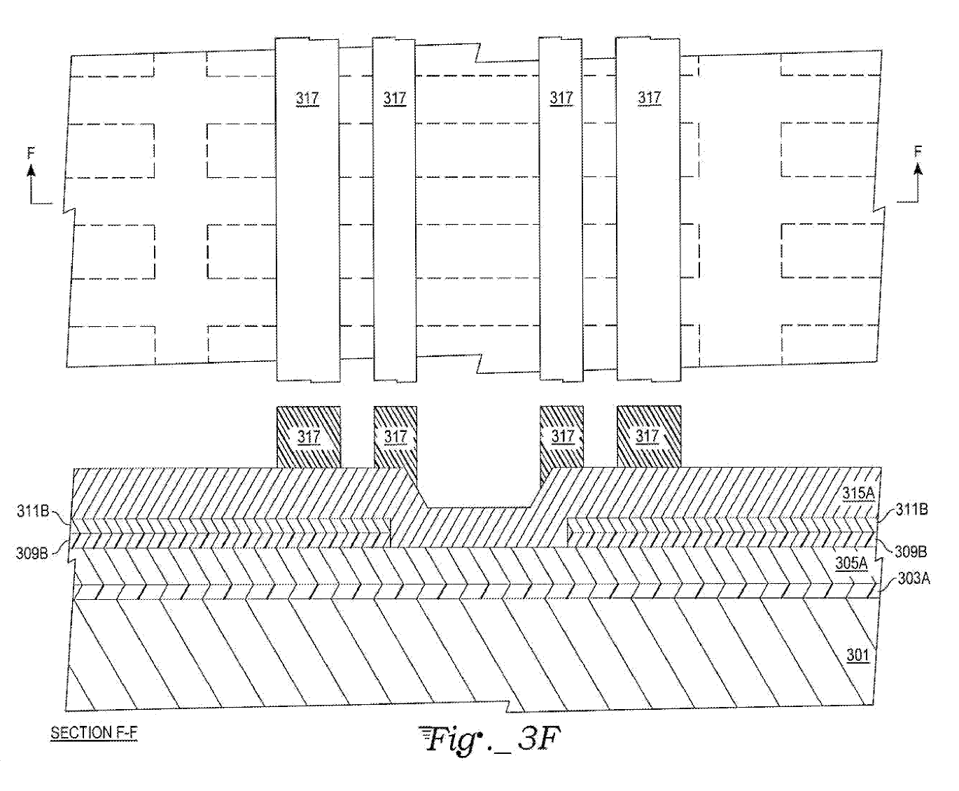

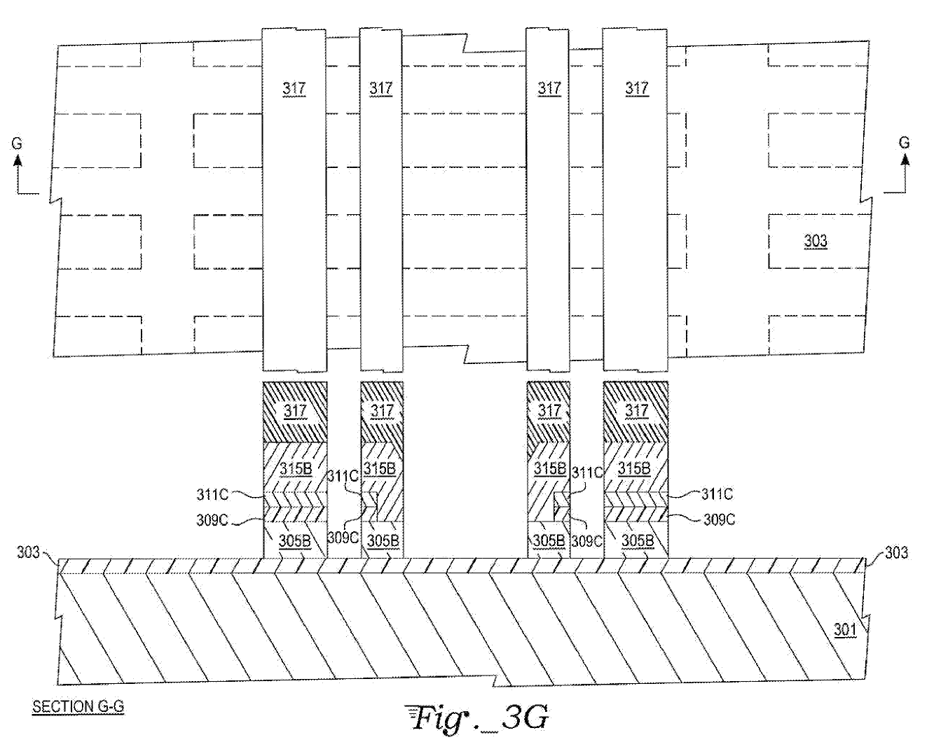

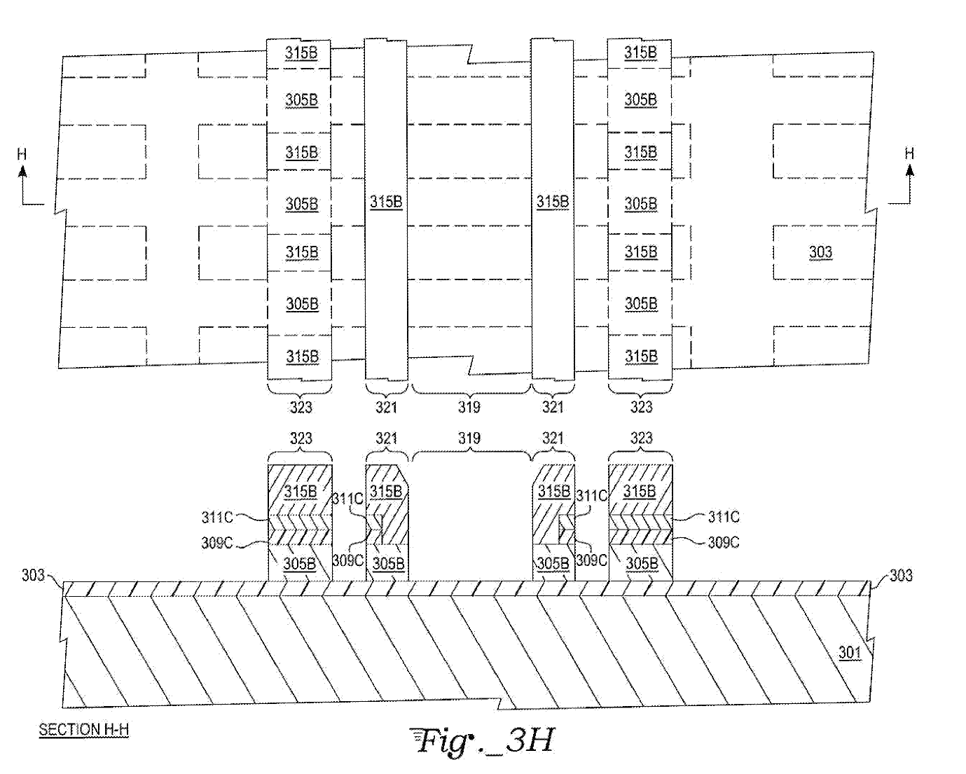

In section A-A of FIG. 3A, a substrate 301 has a gate dielectric layer 303A and a floating polysilicon floating gate layer 305A. The substrate 301 may be comprised of various materials known in the semiconductor art. Such materials include silicon (or other group IV semiconducting materials), compound semiconductors (e.g., compounds of elements, especially elements from periodic table Groups III-V and II-VI). quartz photomasks (e.g., with a deposited and annealed polysilicon layer or a deposited/sputtered metal layer over one surface), or other suitable materials. Frequently, the substrate 301 will be selected based upon an intended use of a finalized memory product. For example, a memory cell used as a component in an integrated circuit for a computer may be formed on a silicon wafer. A memory cell used for lightweight applications or flexible circuit applications, such as a cellular telephone or personal data assistant (PDA), may form the memory cell on a polyethyleneterephthalate (PET) substrate deposited with silicon dioxide and polysilicon followed by an excimer laser annealing (ELA) anneal step.

If the substrate 301 is chosen to be comprised of silicon, the gate dielectric layer 303A may be a thermally-grown silicon dioxide layer. Alternatively, the gate dielectric layer 303A may be a deposited layer, for example, a silicon dioxide layer deposited by atomic layer deposition (ALD) techniques. In other embodiments, the gate dielectric layer 303A may be chosen to be comprised of a high-k dielectric layer such as a high dielectric constant (high-k) dielectric material. High-k dielectric materials are known in the art and include films such as tantalum pentoxide )Ta₂O₅), zirconium oxide (ZrO₂), hafnium oxide (HfO₂), and lead-zirconate-titanate (PZT). However, other high quality dielectric materials may be employed as well. Depending upon the material selected, the gate dielectric layer 303A may be from 30 Å to 80 Å in thickness.

In this exemplary embodiment, the polysilicon gate layer 305A has already been patterned and etched as a series of ridges as indicated in the plan view of FIG. 3A. To pattern the polysilicon gate layer 305A, a first photomask (not shown) is used having one or more slots in a first direction (i.e., the slots are substantially at an angle of 0° with regard to later-constructed bitlines 307). The first photomask thus has a series of slots with an aspect ration (i.e., a length to width ratio as observed from a plan view of the mask) greater than, for example, 2:1. However, the first photomask is a simple geometry photomask. “Simple geometry” in this context refers to the photomask being neither an OPC nor a PSM type mask and thus requires no resulting diffraction patterns or other features to function as intended. The later-constructed bitlines are shown at this stage for reference only. The polysilicon floating gate layer 305A may be 150 Å to 500 Å in thickness.

In FIG. 3B, a second dielectric layer 309A and a second polysilicon layer 311A are confomally formed over the polysilicon gate layer 305A. The second dielectric layer 309A may be comprised of a dielectric film stack. For example, the second dielectric layer 309A may be comprised of thin layers of silicon dioxide, silicon nitride, and silicon dioxide (a skilled artisan will recognize this as an ONO layer). The second polysilicon layer 311A is typically a thin polysilicon layer less than 500 Å in thickness.

With reference to FIG. 3C, a first photoresist layer 313 is patterned and etched. In FIG. 3D, the first photoresist layer 313 provides an etch mask for a first selective etch of the second polysilicon layer 311A (FIG. 3C). The first selective etch is performed producing an etched second polysilicon layer 311B. The first selective etch utilizes an uppermost surface of the second dielectric layer 309A (FIG. 3C) as an etch-stop. A second selective etch produces etched second dielectric layer 309B. The second dielectric etch utilizes an uppermost surface of the polysilicon gate layer 305A as an etch-stop. Selective etching techniques, including appropriate etchants, are known to a skilled artisan.

In FIG. 3E, the first photoresist layer 313 (FIG. 3D) is removed and a conformally-deposited polysilicon control gate layer 315A is formed. A second photoresist layer 317 (FIG. 3F) is patterned and etched using a second photomask (not shown). The second photomask is a simple geometry mask and has slots arranged in a direction substantially orthogonal to slots on the first photomask (described with reference to FIG. 3A). The slots on the second photomask are therefore substantially at an angle of 90° with regard to the later-constructed bitlines 307.

With reference to FIG. 3G, a series of selective etches which etch through exposed polysilicon and dielectric layers down to the gate dielectric layer 303 are performed. The series of selective etches thus produces a plurality of polysilicon floating gates 305B, etched dielectric regions 309C, etched second polysilicon regions 311C, and control gates 315B. Specifically, the two innermost film stacks each have the control gates 315B in direct electrical communication with the underlying polysilicon floating gates 305B. Consequently, the innermost film stacks form select transistors.

Referencing FIG. 3H, a skilled artisan will recognize distinct areas of the portion of the nearly completed EEPROM memory cell. The areas include a region for eventual bitline contacts 319, a plurality of select transistor regions 321, and a plurality of memory cell transistor regions 323. Significantly, the polysilicon floating gates 305B are essentially rectangular/square in shape and may be constructed below a limit-of-resolution of the optical photolithography system employed through the use of the two simple geometry photomasks.

To facilitate an understanding of the present invention, a process and arrangement for forming a portion of an EEPROM memory cell is discussed herein. However, the novel invention disclosed herein is also useful for forming a wide range of other electronic device types and structures having utility as individual devices or in combination with other device types.

For example, although an embodiment depicts formation of a floating gate, a skilled artisan will recognize that the present invention is readily adaptable to any small feature needed for an electronic device such as gate-source-drain features in a vertical CMOS transistor. Additionally, many industries allied with the semiconductor industry could make use of this technique. For example, a thin-film head (TFH) process in the data storage industry or an active matrix liquid crystal display (AMLCD) in the flat panel display industry could readily make use of the processes and techniques described herein. The term “semiconductor” should be recognized as including the aforementioned and related industries.

Additionally, although process steps and techniques are shown and described in detail, a skilled artisan will recognize that other techniques and methods may be utilized which are still included within the scope of the appended claims. For example, there are frequently several techniques used for depositing a film layer (e.g., chemical vapor deposition, plasma-enhanced vapor deposition, epitaxy, atomic layer deposition, etc.). Although not all techniques are amenable to all film types described herein, one skilled in the art will recognize that multiple methods for depositing a given layer and/or film type may be used. Also, a skilled artisan recognizes that various “polarity-reversing” modifications may be made to photomasks described depending upon whether the masks are designed to function with positive or negative photoresist. The specification and drawings are, accordingly, to be regarded in an illustrative rather than a restrictive sense.

What is claimed is:

1. A method of fabricating one or more floating gate elements in an EEPROM memory cell, the method comprising:
forming a gate oxide layer on a substrate;
forming a polysilicon layer over the gate oxide;
patterning the polysilicon layer into one or more ridges with a photolithographic system, the one or more ridges being formed from an image produced by a first simple geometry photomask, the first simple geometry photomask having at least one first feature; and
patterning the one or more ridges into the one or more floating gate elements, the one or more floating gate elements being essentially rectangular in shape and formed from an image produced by a second simple geometry photomask, the second photomask having at least one second feature arranged substantially orthogonal to the at least one first feature on the first photomask.

2. The method of claim 1 wherein the at least one feature on each of the photomasks is selected to be a slot.

3. The method of claim 1 wherein an aspect ratio of the features on each of the photomasks is selected to be greater than 2:1.

4. The method of claim 1 wherein the one or more floating gate elements have at least one dimension less than a limit-of-resolution of the photolithographic system, the at least one dimension being measured in a plane substantially parallel to a face of the substrate.

5. A method of fabricating one or more floating gate elements in an EEPROM memory cell, the method comprising:
forming a polysilicon layer on a substrate;
forming a first photoresist layer over the polysilicon layer;
selecting a first simple geometry photomask having at least one first slot-like feature;
projecting an image onto the first photoresist layer from the first simple geometry photomask using a photolithographic system;
etching the polysilicon layer, thereby forming at least one ridge;
forming a second photoresist layer over the polysilicon layer;
selecting a second simple geometry photomask having at least one second slot-like feature, the at least one second slot-like feature being arranged substantially orthogonal to the at least one first slot-like feature on the first simply geometry photomask;
projecting an image onto the second photoresist layer from the second simple geometry photomask using the photolithographic system; and
etching the polysilicon layer, thereby forming the floating gate.

6. The method of claim 5 further comprising forming a gate oxide layer over the substrate prior to forming the polysilicon layer.

7. The method of claim 5 further comprising selecting an aspect ratio of each of the slot-like features to be greater than 2:1.

8. The method of claim 5 wherein the one or more floating gate elements have at least one dimension less than a limit-of-resolution of the photolithographic system, the at least one dimension being measured in a plane substantially parallel to a face of the substrate.

9. A method of fabricating one or more structures in an electronic device, the method comprising:
forming a first film layer on a substrate;
patterning the first film layer into one or more ridges being formed from an image produced by a first simple geometry photomask, the first simple geometry photomask having at least one first slot-like feature;
patterning the one or more ridges into the one or more structures, the one or more structures being essentially rectangular in shape and formed from an image produced by a second simple geometry photomask, the second simple geometry photomask having at least one second slot-like feature arranged substantially orthogonal to the at least one first slot-like feature on the first photomask, the one or more structures further having at least one dimension less than a limit-of-resolution of the photolithographic system, the at least one dimension being measured in a plane substantially parallel to a face of the substrate.

10. The method of claim 9 further comprising selecting an aspect ratio of each of the slot-like features to be greater than 2:1.
